(19) United States
(12) Patent Application Publication
(10) Pub. No.: US 2021/0020455 A1
(43) Pub. Date: Jan. 21, 2021

(54) CONDUCTIVE VIA STRUCTURE

(71) Applicant: NANYA TECHNOLOGY CORPORATION, New Taipei City (TW)

(72) Inventor: Shing-Yih SHIH, New Taipei City (TW)

(21) Appl. No.: 16/514,986

(22) Filed: Jul. 17, 2019

(51) Int. Cl. H01L 21/48; H01L 23/29; H01L 23/538

(52) U.S. Cl. CPC H01L 21/486; H01L 23/5384; H01L 23/291

(57) ABSTRACT

A conductive via structure includes a first dielectric layer, a conductive pad, a second dielectric layer, and a redistribution layer. The conductive pad is in the first dielectric layer. The second dielectric layer is disposed above the first dielectric layer and has an opening. The conductive pad is in the opening. The opening has a first width at a top surface of the second dielectric layer and a second width at a bottom surface of the second dielectric layer. A difference between the first width and the second width is in a range from about 1.5 um to about 3 um. The redistribution layer extends from the top surface of the second dielectric layer to the conductive pad.

### BACKGROUND

### Field of Invention

The present invention relates to a conductive via structure.

### Description of Related Art

In the fabrication process of a redistribution layer through aluminum deposition, grands of aluminum may affect the efficiency of the subsequent process and the performance of the device. Therefore, in order to avoid formation of grains, the temperature of the aluminum deposition process may be lower. However, the lower temperature makes the thickness of the redistribution layer formed within the opening of the dielectric layer (for example, the conductive via) become thinner. Moreover, aluminum clusters may be formed at the top region of the opening, such that the aluminum deposition efficiency becomes worse. As a result, the electrical connection quality may be degraded.

On the other hand, the greater opening may provide more space for aluminum to be deposited within the opening. However, the greater size of the opening may limit the shrinkage level of the device. As a result, the fabrication of a conductive via structure cannot obey the design rule.

### SUMMARY

The invention provides a conductive via structure.

In some embodiments, the conductive via structure includes a first dielectric layer, a conductive pad, a second dielectric layer, and a redistribution layer. The conductive pad is in the first dielectric layer. The second dielectric layer is disposed above the first dielectric layer and has an opening. The conductive pad is in the opening. The opening has a first width at a top surface of the second dielectric layer and a second width at a bottom surface of the second dielectric layer. A difference between the first width and the second width is in a range from about 3 um to about 6 um. The redistribution layer extends from the top surface of the second dielectric layer to the conductive pad.

In some embodiments, the second dielectric layer has an oblique surface between the top surface and the bottom surface of the second dielectric layer.

In some embodiments, the first width of the opening of the second dielectric layer is greater than 8 um.

In some embodiments, the first width of the opening of the second dielectric layer is in a range from about 9 um to about 13 um.

In some embodiments, the second width of the opening of the second dielectric layer is in a range from about 3 um to about 7 um.

In some embodiments, a ratio of the first width to the second width is in a range from about 1.5 to about 2.2.

In some embodiments, the opening further includes a third width between the top surface and the bottom surface of the second dielectric layer, and the third width is smaller than the first width, and the third width is greater than the second width.

In some embodiments, the third width is gradually decreased from the top surface of the second dielectric layer to the bottom surface of the second dielectric layer.

In some embodiments, the second dielectric layer includes a top portion and a bottom portion below the top portion, and the opening in the top portion has the first width that is substantially constant.

In some embodiments, the conductive pad has a recess interconnecting with the opening of the second dielectric layer.

In some embodiments, a thickness of the redistribution layer on the top surface of the second dielectric layer is in a range from about 4 um to about 5 um.

In some embodiments, the redistribution layer in the opening of the second dielectric layer has a sidewall surrounding a sub opening, and a fourth width of the sub opening is substantially the same.

In some embodiments, a thickness of the sidewall of the redistribution layer is gradually decreased from the top surface of the second dielectric layer to the bottom surface of the second dielectric layer.

In some embodiments, the second dielectric layer is a composite layer.

In the aforementioned embodiments, since the first width of the second dielectric layer is about 3 um to about 6 um greater than the second width of the second dielectric layer, clusters would not be formed at the top region of the opening during the aluminum deposition process. In other words, the portion of the redistribution layer 140 within the opening can be thicker. Therefore, the electrical connection quality of the conductive via structure can be improved.

These and other features, aspects, and advantages of the present invention will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of a conductive via structure according to some embodiments of the present disclosure;

FIG. 2 is a cross-sectional view of the conductive via structure taken along line 2-2 shown in FIG. 1;

FIG. 3 is a cross-sectional view of the conductive via structure shown in

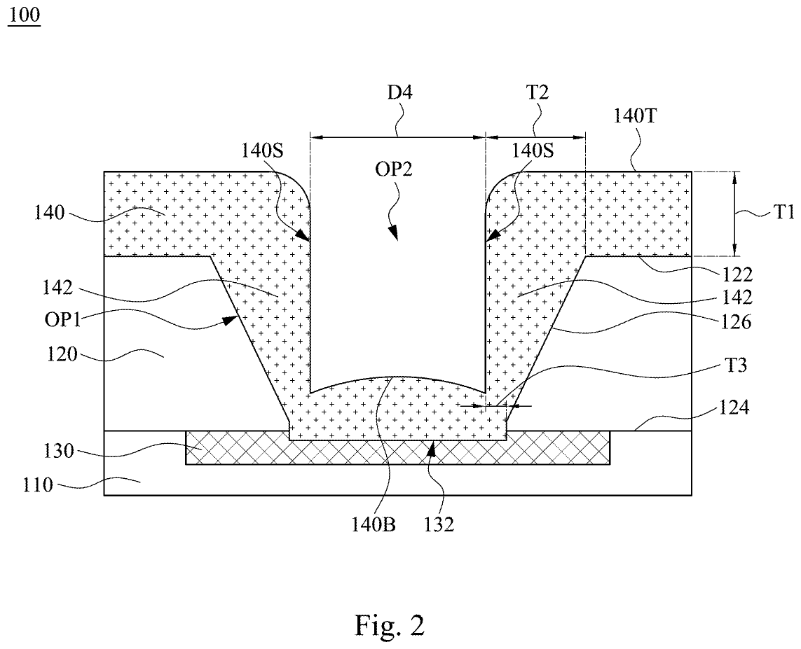

FIG. 2, in which the redistribution layer is omitted; and

FIG. 4 is a cross-sectional view of a conductive via structure according to another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

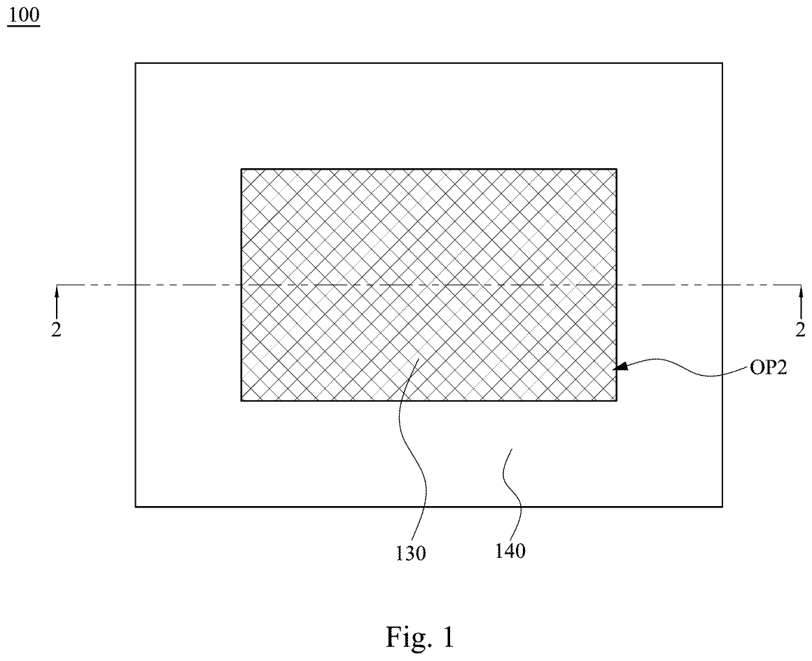

FIG. 1 is a top view of a conductive via structure 100 according to some embodiments of the present disclosure. FIG. 2 is a cross-sectional view of the conductive via structure 100 taken along line 2-2 shown in FIG. 1. Reference is made to FIGS. 1 and 2. The conductive via structure 100 includes a first dielectric layer 110, a second dielectric layer 120, a conductive pad 130, and a redistribution layer 140. In some embodiments, a substrate, such as a silicon substrate, a semiconductor substrate, or the like, may be located below the first dielectric layer 110 to support and electrically connect to the conductive pad 130. The conductive pad 130 is in the first dielectric layer 110. The second dielectric layer 120 is disposed above the first dielectric layer 110 and has an opening OP1. The conductive pad 130 is in the opening OP1. The second dielectric layer 120 has a top surface 122 and a bottom surface 124 opposite to the top surface 122. The bottom surface 124 is in contact with the first dielectric layer 110 and the conductive pad 130. As shown in FIG. 2, the redistribution layer 140 extends from the top surface 122 of the second dielectric layer 120 to the conductive pad 130.

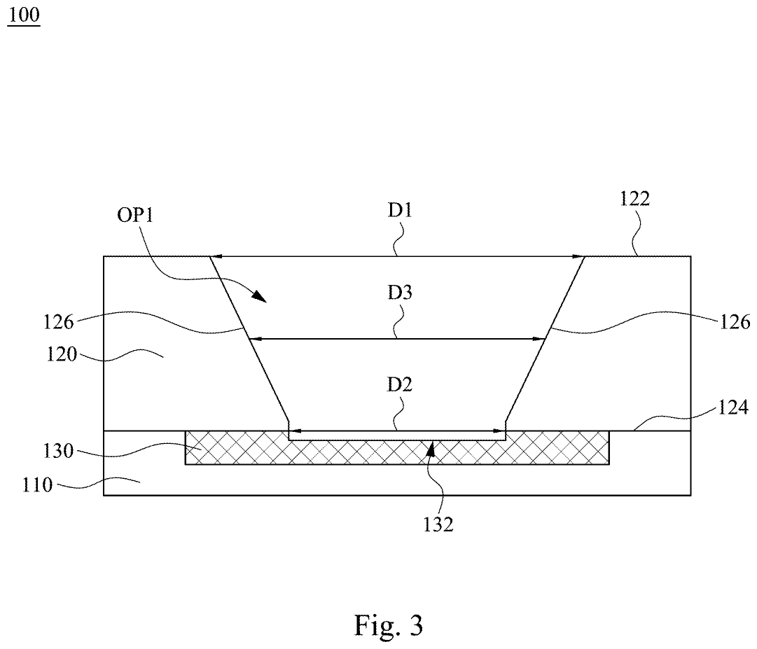

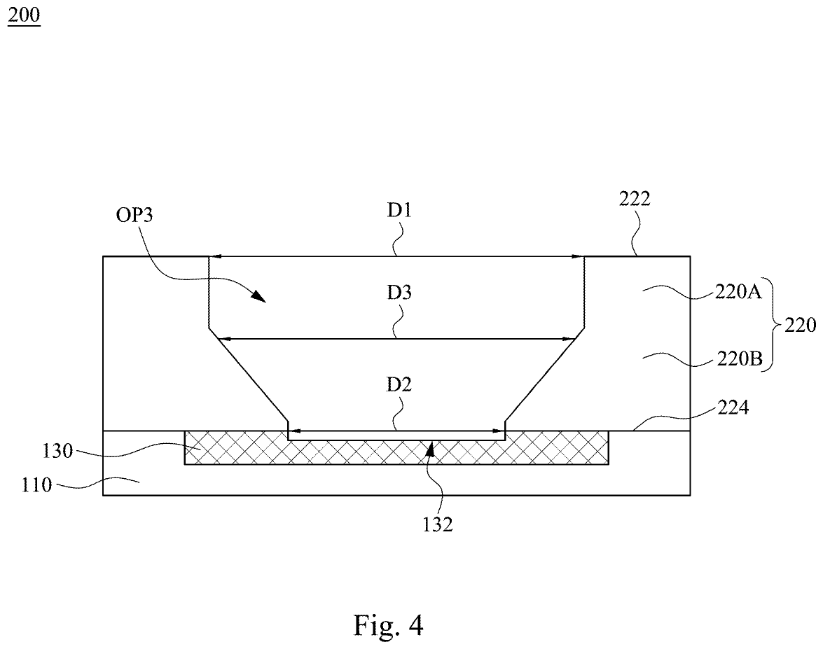

FIG. 3 is a cross-sectional view of the conductive via structure 100 shown in FIG. 2, in which the redistribution layer 140 is omitted. For clarity, the configuration of the second dielectric layer 120 will be described in detail. The opening OP1 of the second dielectric layer 120 has a first width D1 at the top surface 122 of the second dielectric layer 120 and a second width D2 at the bottom surface 124 of the second dielectric layer 120. As shown in FIG. 3, the first width D1 is greater than the second width D2. A difference between the first width D1 and the second width D2 is in a range from about 3 um to about 6 um. The second dielectric layer 120 has an oblique surface 126 between and connected to the top surface 122 and the bottom surface 124. In other words, the opening OP1 is the space formed by the oblique surface 126 of the second dielectric layer 120. In the present embodiment, the opening OP1 is rectangular, and the first width D1 and the second width D2 are the distances between two oblique surface 126 that are opposite to each other. In some other embodiments, the opening OP1 is circular, and the first width D1 and the second width D2 are diameters of opening OP1.

In some embodiments, the second dielectric layer 120 is a composite layer. A material of the composite layer includes silicon oxide (SiO₂) and silicon nitride (SiN). In some embodiments, a thickness of the second dielectric layer 120 is in a range from about 5 um to about 8 um.

In some embodiments, the first width D1 of the opening OP1 of the second dielectric layer 120 is greater than 8 um. In some other embodiments, the first width D1 of the opening OP1 of the second dielectric layer 120 is in a range from about 9 um to about 13 um. The second width D2 of the opening OP1 of the second dielectric layer 120 is in a range from about 3 um to about 7 um. In some embodiments, a ratio of the first width D1 to the second width D2 is in a range from about 1.5 to about 2.2.

In the present embodiments, the opening OP1 further includes a third width D3 between the top surface 122 and the bottom surface 124 of the second dielectric layer 120. The third width D3 is smaller than the first width D1, and the third width D3 is greater than the second width D2. Specifically, in the present embodiment, the third width D3 is gradually decreased from the top surface 122 of the second dielectric layer 120 to the bottom surface 124 of the second dielectric layer 120.

In some embodiments, the conductive pad 130 includes a recess 132 located below the opening OP1. In other words, the recess 132 of the conductive pad 130 is communicated with the opening OP1.

Reference is made to FIG. 2, the redistribution layer 140 covers the top surface 122 and the oblique surface 126 of the second dielectric layer 120. Moreover, the redistribution layer 140 extends to the recess 132 of the conductive pad 130, such that the redistribution layer 140 is electrically connected to the conductive pad 130. The redistribution layer 140 on the top surface 122 of the second dielectric layer 120 may be electrically connected to a conductive structure, such as a solder ball, solder bump, or the like.

A portion of the redistribution layer 140 in the opening OP1 of the second dielectric layer 120 has a sidewall 142. The redistribution layer 140 has a sub opening OP2 surrounded by the sidewall 142. The sub opening OP2 of the redistribution layer 140 is in the opening OP1 of the second dielectric layer 120. The sub opening OP2 is in the opening OP1. In the present embodiment, the sub opening OP2 has a fourth width D4 that is substantially the same. In other words, the inner surface 140S of the redistribution layer 140 is substantially straight. In some other embodiments, the fourth width D4 may be gradually decreased from a top surface 140T of the redistribution layer 140 to a bottom surface 140B of the redistribution layer 140. Accordingly, the fourth width D4 proximal to the top surface 122 of the second dielectric layer 120 is greater than or equal to the fourth width D4 proximal to the bottom surface 124 of the second dielectric layer 120.

A portion of the redistribution layer 140 on the top surface 122 of the second dielectric layer 120 has a first thickness T1. The first thickness T1 is a distance between the top surface 140T of the redistribution layer 140 and the top surface 122 of the second dielectric layer 120. The thickness T1 is in a range from about 4 um to about 5 um. In some embodiments, the sidewall 142 of the redistribution layer 140 has a second thickness T2 proximal to the top surface 122 of the second dielectric layer 120 and a third thickness T3 proximal to the bottom surface 124 of the second dielectric layer 120. Each of the second thicknesses T2 and T3 is a distance between the inner surface 140S of the redistribution layer 140 and the oblique surface 126 of the second dielectric layer 120. In the present embodiment, the second thickness T2 of the sidewall 142 of the redistribution layer 140 is greater than the third thickness T3 of the sidewall 142 of the redistribution layer 140. Specifically, the thickness of the sidewall 142 of the redistribution layer 140 is gradually decreased from the top surface 122 of the second dielectric layer 120 to the bottom surface 124 of the second dielectric layer 120.

As described above, since the first width D1 of the second dielectric layer 120 is about 3 um greater to about 6 um than the second width D2 of the second dielectric layer 120 (see FIG. 3), the first width D1 is greater than 8 urn, the second width D2 is in a range from about 3 urn to about 7 urn, the material of the redistribution layer 140 (e.g., aluminum) would not be clustered at the top region of the opening OP1 (see FIG. 2). Therefore, the aluminum deposition efficiency for forming the redistribution layer 140 in the opening OP1 may be improved, and the redistribution layer 140 may have a thicker sidewall 142. With such configuration, the electrical connection quality of the conductive via structure 100 can be improved.

Specifically, since the operation temperature during the typical aluminum deposition is lower (for example, about 200 ° C.), there is no re-flow process employed. As a result, it's hard to form the sidewall 142 of the redistribution layer 140 with a thickness that can provide sufficient electrical connection quality. In some embodiments, in order to provide sufficient electrical connection quality between the sidewall 142 of the redistribution layer 140 and the conductive pad 130, the third thickness T3 of the sidewall 142 may be greater than 600 nm.

For example, Table 1 shows three exemplary conductive via structures, Samples 1-3. Samples 1-3 have different first widths D1 and third thicknesses T3.

TABLE 1

| | D1 (um) | T3 (nm) |
|---|---|---|
| Sample 1 | 7.91 | 400 |
| Sample 2 | 8.41 | 740 |
| Sample 3 | 9.21 | 840 |

As shown in Table 1, Sample 1 has a first width D1 that is smaller than 8 um. Therefore, the third thickness T3 is smaller than 600 nm. On the other hand, Samples 2-3 each has a first width D1 that is greater than 8 um. As such, the third thicknesses T3 may be both greater than 600 nm. Moreover, as shown in Samples 1-3, the greater the first widths D1 are, the thicker the sidewalls 142 are formed.

Table 2 shows two exemplary conductive via structures, Samples 4-5. Samples 4-5 have different first widths D1, differences between the first width D1 and the second width D2 (D1-D2), and third thicknesses T3.

TABLE 2

| | D1 (um) | D1-D2 (um) | T3 (nm) |
|---|---|---|---|
| Sample 4 | 9.13 | 3.14 | 650 |
| Sample 5 | 9.21 | 4.09 | 760 |

As shown in Table 2, Sample 4 and Sample 5 each has a first width D1 that is greater than 8 um and a difference between the first width D1 and the second width D2 that is greater than 3 um. Therefore, the third thicknesses T3 are both greater than 600 nm. Moreover, although the first widths D1 of Sample 4 and Sample 5 are similar, the thicknesses T3 is greater when the difference between the first width D1 and the second width D2 is greater. That is, as long as the differences between the first width D1 and the second width D2 are greater than 3 urn, the thicknesses T3 of the sidewall 142 can be as thick as the desired value or be thicker than the desired value (e.g., 600 nm). Therefore, the first width D1 can be smaller, for example, smaller than 13 urn. Accordingly, the minimization of the conductive via structure 100 can be achieved.

According to Samples 1-5, with the configurations of the second dielectric layer 120 described above, clusters of the redistribution layer 140 would not be formed at the top region of the opening OP1 during the aluminum deposition process. Therefore, it is easier to deposit a thicker sidewall 142 of the redistribution layer 140. With such configuration, the electrical connection quality of the conductive via structure 100 can be improved.

It is to be noted that the connection relationships of the elements described above will not be repeated in the following description, and only aspects related to another type of the second dielectric layer will be described.

FIG. 4 is a cross-sectional view of a conductive via structure 200 according to another embodiment of the present disclosure. The conductive via structure 200 is similar to the conductive via structure 100 in FIG. 3. The difference is that a second dielectric layer 220 of the conductive via structure 200 has a top portion 220A and a bottom portion 220B below the top portion 220A. The bottom portion 220B is located between the top portion 220A and the first dielectric layer 110. In other words, the bottom portion 220B is located between the top portion 220A and the conductive pad 130. The conductive via structure 200 has an opening OP3 surrounded by the top portion 220A and the bottom portion 220B.

The opening OP3 surrounded by the top portion 220A has the first width D1 at the top surface 222 of the second dielectric layer 220 that is substantially the same as the first width D1 described in the conductive via structure 100 of FIG. 1. In the present embodiment, the opening OP3 in the top portion 220A has a constant width.

The opening OP3 surrounded by the bottom portion 220B has a second width D2 at the bottom surface 224 of the second dielectric layer 220 that is substantially the same as the second width D2 described in the conductive via structure 100 of FIG. 1. The opening OP3 in the bottom portion 220B further has a third width D3 between the top portion 220A and the bottom surface 224 of the second dielectric layer 220. The third width D3 is greater than the second width D2 and is smaller than the first width D1. In the present embodiment, the third width D3 of the opening OP3 in the bottom portion 220B is gradually decreased from the top portion 220A to the bottom surface 224 of the second dielectric layer 220.

Other structural details of the conductive via structure 200 are the same as the conductive via structure 100. Accordingly, the conductive via structure 200 has the same advantages as the conductive via structure 100, and a description will not be repeated hereinafter.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A conductive via structure, comprising:
a first dielectric layer;
a conductive pad in the first dielectric layer;
a second dielectric layer disposed above the first dielectric layer and having an opening, wherein the conductive pad is in the opening, the opening has a first width at a top surface of the second dielectric layer and a second width at a bottom surface of the second dielectric layer, and a difference between the first width and the second width is in a range from about 3 um to about 6 um; and
a redistribution layer extending from the top surface of the second dielectric layer to the conductive pad.

2. The conductive via structure of claim 1, wherein the second dielectric layer has an oblique surface between the top surface and the bottom surface of the second dielectric layer.

3. The conductive via structure of claim 1, wherein the first width of the opening of the second dielectric layer is greater than 8 um.

4. The conductive via structure of claim 1, wherein the first width of the opening of the second dielectric layer is in a range from about 9 um to about 13 um.

5. The conductive via structure of claim 1, wherein the second width of the opening of the second dielectric layer is in a range from about 3 um to about 7 um.

6. The conductive via structure of claim 1, wherein a ratio of the first width to the second width is in a range from about 1.5 to about 2.2.

7. The conductive via structure of claim 1, wherein the opening further comprises a third width between the top surface and the bottom surface of the second dielectric layer, and wherein the third width is smaller than the first width, and the third width is greater than the second width.

8. The conductive via structure of claim 7, wherein the third width is gradually decreased from the top surface of the second dielectric layer to the bottom surface of the second dielectric layer.

9. The conductive via structure of claim 1, wherein the second dielectric layer comprises a top portion and a bottom portion below the top portion, and the opening in the top portion has the first width that is substantially constant.

10. The conductive via structure of claim 1, wherein the conductive pad has a recess communicating with the opening of the second dielectric layer.

11. The conductive via structure of claim 1, wherein a thickness of the redistribution layer on the top surface of the second dielectric layer is in a range from about 4 um to about 5 um.

12. The conductive via structure of claim 1, wherein the redistribution layer in the opening of the second dielectric layer has a sidewall surrounding a sub opening, and a fourth width of the sub opening is substantially the same.

13. The conductive via structure of claim 12, wherein a thickness of the sidewall of the redistribution layer is gradually decreased from the top surface of the second dielectric layer to the bottom surface of the second dielectric layer.

14. The conductive via structure of claim 1, wherein the second dielectric layer is a composite layer.
